(19) United States
(12) Patent Application Publication
(10) Pub. No.: US 2008/0104490 A1
(43) Pub. Date: May 1, 2008

(54) DIGITAL DATA DECODING APPARATUS AND DIGITAL DATA DECODING METHOD

(75) Inventors: Norikatsu Chiba, Tokyo (JP); Toshifumi Yamamoto, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 11/858,092

(22) Filed: Sep. 19, 2007

(30) Foreign Application Priority Data
Oct. 31, 2006 (JP) 2006-296365

(51) Int. Cl. H03M 13/03

(52) U.S. Cl. 714/796

(57) ABSTRACT

According to one embodiment, a digital data decoding apparatus calculates branch metrics of all paths in an input data series from the path at a state of a current time to the path at a state of a next time, and obtains path metrics of all the paths up to the path at the state of the next time by adding the calculated branch metric to the path metric of the path corresponding to the branch metric. Further, the digital data decoding apparatus selects a maximum-likelihood path from among the paths based on the obtained path metrics and, when no input is performed, selects the maximum-likelihood path by utilizing the path metric of the selected maximum-likelihood path as it is without adding the branch metric thereto.

### CROSS-REFERENCE TO RELATED APPLICATIONS

This application is based upon and claims the benefit of priority from Japanese Patent Application No. 2006-296365, filed Oct. 31, 2006, the entire contents of which are incorporated herein by reference.

### BACKGROUND

1. Field

One embodiment of the invention relates to a digital data decoding apparatus and a digital data decoding method, which are applied to a data reproducing apparatus such as an optical disk device and a hard disk drive performing a signal processing by PRML method.

2. Description of the Related Art

Conventionally, as a recording media capable of recording and reproducing digital data, there is an optical disk represented by a DVD (digital versatile disk) or a magnetic disk. Of these, as for the optical disk such as a DVD-RAM being a DVD family as an example, a signal recording layer is provided in the recording medium (disk), and when a laser beam having appropriate energy is emitted to the recording layer, the crystal state of the recording layer makes a change, and when the laser beam having appropriate energy is emitted again to the recording layer, a reflected light in accordance with the crystal state of the recording medium can be obtained. It is designed that the digital data is reproduced by detecting this reflected light.

Meanwhile, in recent years, with an aim to realize high-density recoding/reproduction, a technology (PRML technology) of a system called PRML (Partial Response Maximum Likelihood) is adopted in data reproducing apparatuses reproducing digital data recoded in the recording medium such as the optical disk and information recording apparatuses recoding digital data in the recoding medium, and further hard disk drives using a magneto-resistive (MR) head. The PRML technology is a system combining a later-shown partial response system and a Viterbi decoding system of which details are disclosed in Japanese Patent Application Publication (KOKAI) No. 2001-195830 (Patent document 1) and so forth.

Here, the partial response system (PR) is a system reproducing the digital data by realizing a reproducing circuit without the need of high-frequency component, by compressing necessary signal band by actively using an inter-symbol interference (an interference between reproduced signals caused when adjacent recoded bits enter into a light spot).

Meanwhile, the Viterbi decoding system (ML) is a kind of a so-called maximum likelihood sequence estimation system and is a system reproducing the digital data based on signal amplitude information over a plurality of times by effectively using an inter-symbol interference rule of a reproduced waveform.

Conventionally, the PRML technology is realized by a PLL circuit, an AD converter, a FIR (Finite Impulse Response) filter and a Viterbi decoder, in which the process is executed in accordance with a reproduction clock. The reproduction clock is synchronized with a clock component (also called a channel bit rate) of the digital data recorded in the recoding medium, and generated by the PLL circuit.

However, when the digital data reproduction is performed at a higher magnification speed (high-power speed) with respect to a standard reproduction speed, a power consumption increase is caused due to an increase in the reproduction clock frequency. Accordingly, conventionally, there is a technology (for example, see Japanese Patent Application Publication (KOKAI) No. 2002-269925 (Patent document 2)) in which data decoding is performed using a reproduction clock synchronized with a half frequency of a channel bit rate to prevent power consumption from increasing even when the reproduction is performed at a high magnification speed.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary block diagram showing an internal configuration of a Viterbi decoder according to a first embodiment of the invention;

FIG. 2 is an exemplary block diagram showing an example internal configuration of a data reproducing apparatus having the Viterbi decoder in the first embodiment incorporated therein;

FIG. 3 is an exemplary view showing an impulse response waveform of a PR (12221) in the embodiment;

FIG. 4 is an exemplary diagram showing a state transition in a channel rate Viterbi decoder in the embodiment;

FIG. 5 is an exemplary diagram showing a state transition in a Viterbi decoder in the embodiment;

FIG. 6 is an exemplary block diagram showing an example internal configuration of a Viterbi decoder according to a second embodiment of the invention; and

FIG. 7 is an exemplary block diagram showing an example internal configuration of a Viterbi decoder according to a third embodiment of the invention.

### DETAILED DESCRIPTION

Various embodiments according to the invention will be described hereinafter with reference to the accompanying drawings. In general, according to one embodiment of the invention, a digital data decoding apparatus includes: a branch metric calculating device calculating branch metrics of all paths in an input data series from the path at a state of a current time to the path at a state of a next time; and a path computing device adding the branch metric calculated by said branch metric calculating device to a path metric of the path corresponding to the branch metric to obtain the path metrics of all the paths up to the path at the state of the next time, and selecting a maximum-likelihood path from among the paths based on the obtained path metrics. Further, the path computing device is configured to select the maximum-likelihood path by utilizing the path metrics of the selected maximum-likelihood path as it is without adding the branch metric thereto when no input is performed, is provided.

Further, in a digital data decoding method, branch metrics of all paths in an input data series from the path at a state of a current time to the path at a state of a next time is calculated, the calculated branch metric is added to a path metric of the path corresponding to the branch metric to obtain the path metrics of all the paths up to the path at the state of the next time, and a maximum-likelihood path is selected from among the obtained paths based on the obtained path metrics, and selecting the maximum-likelihood path by utilizing the path metric of the selected maximum-likelihood path as it is without adding the branch metric thereto when the input is not performed.

### First Embodiment

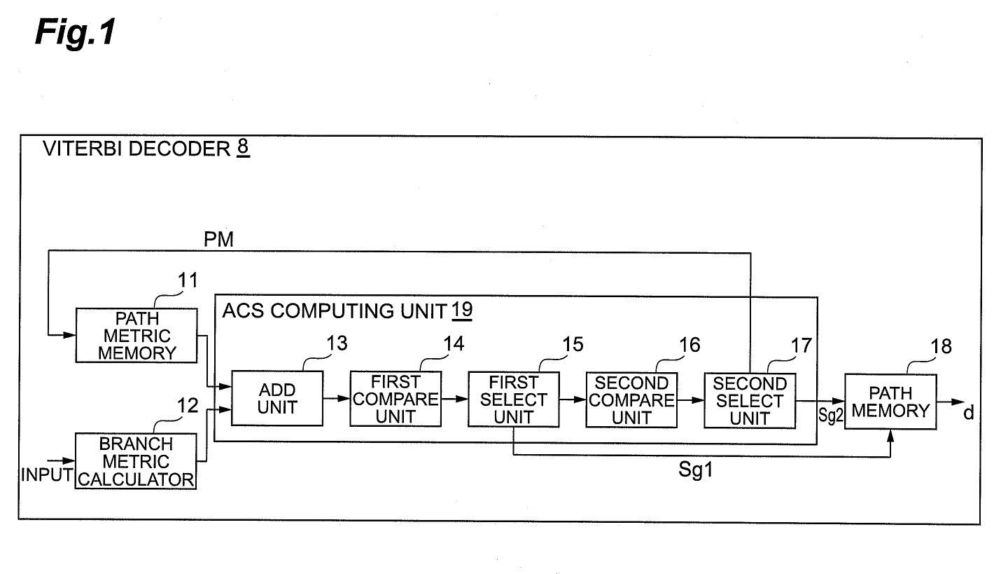

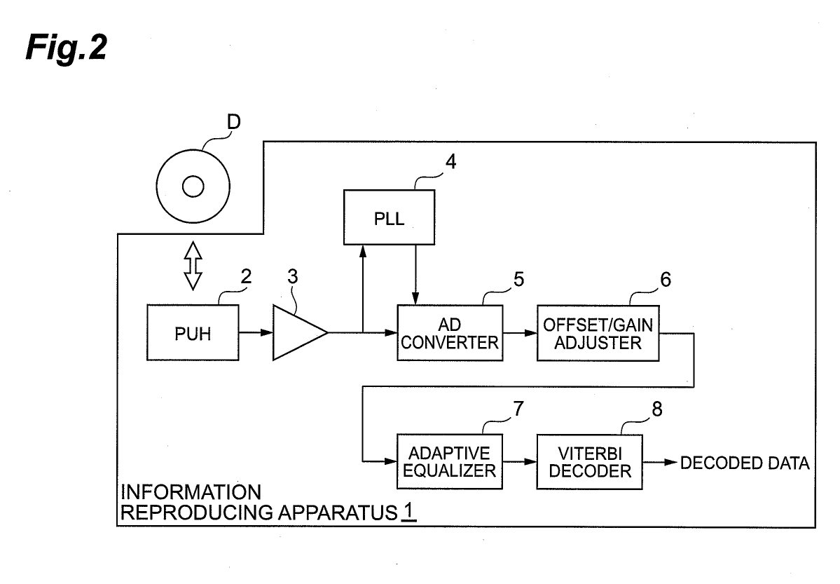

FIG. 1 is a block diagram showing a configuration of a Viterbi decoder 8 as a digital data decoding apparatus according to a first embodiment of the invention, and FIG. 2 is a block diagram showing a configuration of a data reproducing apparatus 1. The Viterbi decoder 8 is incorporated in the data reproducing apparatus 1 shown in FIG. 2, hence, the description will be given of the data reproducing apparatus 1 first.

The data reproducing apparatus 1 uses an optical disk D as a recoding medium as shown in FIG. 2. The data reproducing apparatus 1 reproduces digital data, by a disk reproducing apparatus capable of reproducing digital data recorded in the optical disk D, in compliant with an optical disk standard (for example, DVD).

The data reproducing apparatus 1 includes: a PUH (pick up head) 2 provided with an optical pickup and the like, a preamplifier 3 and a PLL circuit 4. Further, the data reproducing apparatus 1 includes an AD converter 5, an offset gain adjuster 6, an adaptive equalizer 7 and a Viterbi decoder 8.

The PUH 2 emits an appropriate laser beam to the optical disk D to detect a light reflected from the optical disk D and outputs a weak analog reproduced signal to the preamplifier 3. The preamplifier 3 performs a processing such as amplification and the like with respect to the analog reproduced signal outputted from the preamplifier 3 and, after the signal reaches to a sufficient signal level, outputs it to the an AD converter 5.

The PLL circuit 4 inputs the analog reproduced signal and generates a reproduction clock synchronized with a half frequency of a channel bit rate being a clock component that the analog reproduced signal (hereinafter called the “half-rate clock”) has, and then outputs the half-rate clock to the AD converter 5.

The AD converter 5 samples the inputted analog reproduced signals in accordance with the timings of the half-rate clock and converts them into a digital signal series. Note that, in the case below, it is known theoretically by the sampling theorem that the digital data can be decoded even when the AD converter 5 takes the samples in accordance with the half-rate clock. Specifically, in the case where, as a code for the digital data to be demodulated, for example, a code in which a minimum run length is limited to “2” like 8 to 16 modulation codes is in use, and at the same time, MTF (Mutual Transfer Function) characteristics being optical reproduction characteristics are distributed in a band that is approximately a forth (¼) or below of the channel bit rate.

The offset gain adjuster 6 performs an offset adjustment and a gain adjustment with respect to the digital signal series outputted from the AD converter 5, and outputs it to the adaptive equalizer 7.

The adaptive equalizer 7 performs a waveform equalization with respect to the digital signal series outputted from the offset gain adjuster 6 in accordance with the PR characteristic adopted. The adaptive equalizer 7 uses a FIR filter. The FIR filter performs the waveform equalization with respect to the digital signal series using a predetermined filter coefficient and outputs it to the Viterbi decoder 8.

Subsequently, the description will be given of the configuration of the Viterbi decoder 8. The Viterbi decoder 8 includes a path metric memory 11, a branch metric calculator 12, an add unit 13 and a first compare unit 14, as shown in FIG. 1. Further, the Viterbi decoder 8 includes a first select unit 15, a second compare unit 16, a second select unit 17 and a path memory 18.

In the Viterbi decoder 8, add, compare and select are performed with respect to the path metric in a manner as will be described below by the add unit 13, the first compare unit 14, the first select unit 15, the second compare unit 16 and the second select unit 17, which are circuits composing an ACS computing unit 19 as a path computing unit.

The Viterbi decoder 8 is configured to operate in accordance with the half-rate clock generated by the PLL circuit 4. The Viterbi decoder 8 calculates those metrics of the digital signal series inputted from the adaptive equalizer 7 that are at the state of the respective sample points, and then, saves, as a maximum-likelihood path, in sequence, the path that most probably has the smallest metric among the input data series (which is called the maximum-likelihood path and the remaining is called survival path(s)). The Viterbi decoder 8 decodes the digital data by performing this operation repeatedly at each time. Here, the metric indicates an additional value at each state of the branch metric and the branch metric indicates a stochastic length of the each path.

The branch metric calculator 12 calculates the branch metrics of all the paths in the input data series from that at the state of the current time to that at the state of the next time.

The add unit 13 adds the branch metrics of the all the paths calculated by the branch metric calculator 12 to the path metrics of the paths corresponding to the branch metrics, respectively, to thereby obtain the path metrics of all the paths up to the path at the state of the next time (the add of the branch metric by the add unit 13 is called a “branch metric add”).

The first compare unit 14 compares the path metrics of the respective paths obtained by the add unit 13 to obtain the path metric having the smallest value (in the embodiment, this path metric obtained is called a “minimum path metric”).

The first select unit 15 performs a path selection selecting the path corresponding to the minimum path metric obtained by the first compare unit 14 as a most probable path (maximum-likelihood path) and outputs a selection signal sg1 indicating the selected path to the path memory 18.

The path metric PM of the path selected by the first select unit 15 is memorized in the path metric memory 11 via the second compare unit 16 and the second select unit 17 to be used as a path metric at the next time. Also, the path metric PM is used in the comparison of the path metrics in the second compare unit 16 (the detail description will be provided later in this regard). In the first select unit 15, the above-described path selection is performed with respect to the sampling data inputted into the branch metric calculator 12.

Largely different from the Viterbi decoder (hereinafter called the “channel rate Viterbi decoder”) performing the processing at the channel bit rate, the Viterbi decoder 8 has the second compare unit 16 and the second select unit 17. The description as to the second compare unit 16 and the second select unit 17 will be given in detail hereinafter.

The path memory 18 memorizes the survival path(s) obtained in the ACS computing unit 19. The path memory 18 decodes the digital data by tracking back the survival path(s) using the selection signal sg1 outputted by the first select unit 15 and a later-described additional selection signal sg2 outputted from the second select unit 17, and outputs decoded data “d”.

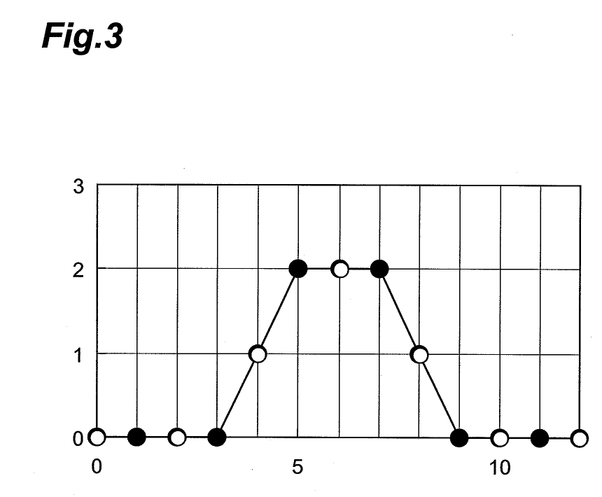

Here, FIG. 3 is a view showing an impulse response waveform of a PR (12221). This PR class is ruled to be used in a HD DVD. When the AD converter 5 takes samples in accordance with the clock synchronized with the channel bit rate, the sampling data at both points represented by white (◯) and black () circles (the data at the respective times composing the input data series) are obtained. However, when the AD converter 5 takes samples in accordance with the half-rate clock, only the sampling data at the point represented by the white circle (◯) or the black circle () is obtained. In that case, the sampling data at the not-inputted side is to be missed.

Therefore, in the Viterbi decoder 8, the number of data of the input data series inputted into the branch metric calculator 12 is a half of that of the channel rate Viterbi decoder. Accordingly, when the input data series is that adopted to the PR (12221) as shown in FIG. 3, only the sampling data at the point represented by either the white circle (◯) or the black circle () is inputted. In that case, the calculation of the branch metric by the branch metric calculator 12 is executed every other time.

However, the Viterbi decoder 8 is needed to output such the number of the decoded data “d” as is equal to the number when operating at the channel bit rate. Specifically, it is necessary that the decoding be performed also to the sampling data not inputted into the branch metric calculator 12 so that the digital data is outputted.

Therefore, the Viterbi decoder 8 is configured to additionally include the second compare unit 16 and the second select unit 17 to thereby generate the additional selection signal sg2 with respect to the sampling data not inputted into the branch metric calculator 12.

Since the number of data inputted into the branch metric calculator 12 is the one half of that of the channel rate Viterbi decoder as described above, and therefore, when no data is inputted into the branch metric calculator 12, neither the addition in the add unit 13 nor the comparison in the first compare unit 14 is performed.

Therefore, the second compare unit 16 is configured to perform the comparison by utilizing the path metric PM of the path selected by the first select unit 15 to thereby obtain the minimum path metric. Further, the second select unit 17 performs a path selection selecting the path corresponding to the minimum path metric (which is called a “path metric for addition” in the embodiment) obtained by the second compare unit 16, as a most probable path (maximum-likelihood path), and outputs a selection signal (hereinafter called “additional selection signal”) sg2 indicating the selected path to the path memory 18. Further, the second select unit 17 lets the path metric memory 11 memorize the path metric PM of the path selected by the second select unit 17 itself and the path metric PM of the path selected by the first select unit 15 to thereby update the path metrics.

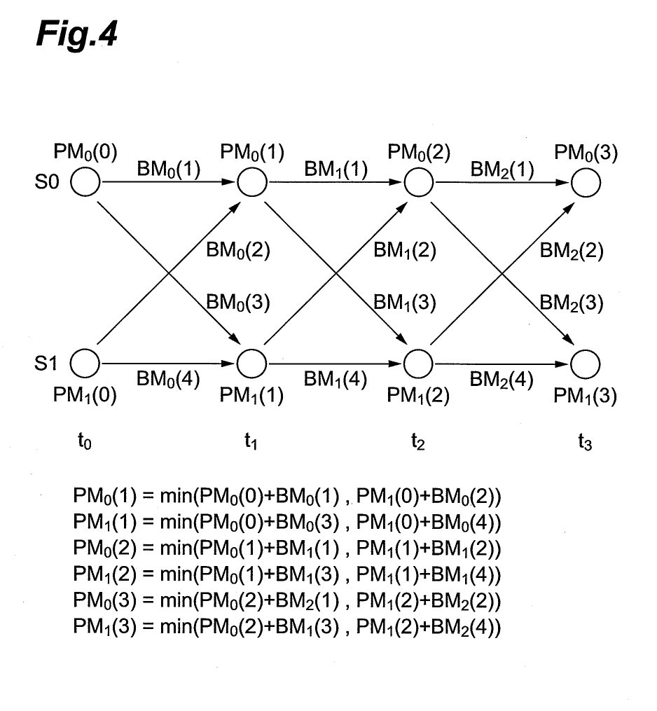

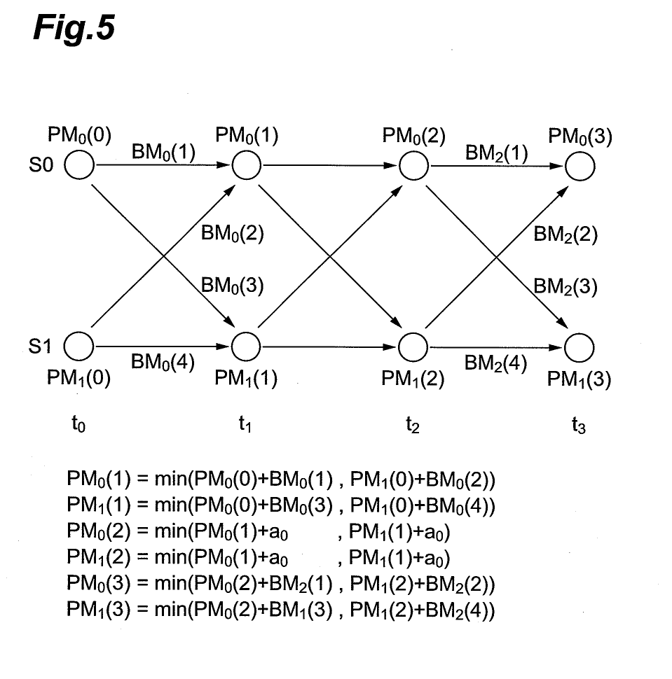

Here, for example, as shown in FIGS. 4 and 5, assuming that there are two states S0 and S1 where the time passes in the order of times t0, t1, t2, t3 (when the time t0 is the current time, then the time t1 is the next time). FIG. 4 shows a state transition diagram in the channel rate Viterbi decoder and FIG. 5 shows a state transition diagram in the Viterbi decoder 8.

In the channel rate Viterbi decoder, the sampling is performed at the clock synchronized with the channel rate, therefore when the path metrics at the states S0, S1 at the time t0, are defined as PM₀ (0), PM₁ (0), respectively, and the branch metrics of every path from the time t0 to the time t1 are defined as BM₀ (1), BM₀ (2), BM₀ (3), BM₀ (4), as shown in the drawing, the path metrics PM₀ (1), PM₁ (1) at the states S0, S1 at the time t1, respectively, can be obtained by an equation 1 and an equation 2 below. Note that “min (A, B)” has a meaning to select a smaller one of A or B in value.

PM₀(1)=min (PM₀(0)+BM₀(1), PM₁(0)+BM₀(2)) Equation 1

PM₁(1)=min (PM₀(0)+BM₀(3) PM₁(0)+BM₀(4)) Equation 2

Hereinafter, similarly, the path metrics at the time t2 and thereafter can be obtained in the manner as shown in FIG. 4.

Meanwhile, the Viterbi decoder 8 is inputted only the one half of the sampling data, therefore, by way of example, when the sampling data at the time t0 is inputted, then the sampling data at the time t1 is not inputted as shown in FIG. 5. In that case, the calculation of the branch metric by the branch metric calculator 12 and the addition by the add unit 13 are not performed. Therefore, the path metric at the time t2 is obtained by the second compare unit 16 and the second select unit 17 by way of performing the path metric computation based on an equation 3 and an equation 4 below, respectively.

In the equation 3 and equation 4, the path metrics PM₀ (1) and PM₁ (1) are used as they are without adding any branch metric thereto.

PM₀(2)=min (PM₀(1), PM₁(1)) Equation 3

PM₁(2)=min (PM₀(1), PM₁(1)) Equation 4

When performed as described above, then, even for the times having no sampling data inputted, the path metric is obtainable, so that the most probable path (maximum-likelihood path) can be obtained.

When the path metric is obtained based on the equation 3 and equation 4, since the path metric at the previous time is used as it is, the comparison between the path metrics having the same value is to be performed by the second compare unit 16.

Further, when obtaining PM₀ (2), PM₁ (2), the branch metric is not calculated by the branch metric calculator 12, hence, the equation 3 and equation 4 are the same as the case where both constant metrics a0 set to the determined values are set to 0 in an equation 5 and an equation 6 below.

PM₀(2)=min (PM₀(1)+a0, PM₁(1)+a0) Equation 5

PM₁(2)=min (PM₀(1)+a0, PM₁(1)+a0) Equation 6

Here, the constant metric a0 may be set to a value set and memorized in a register by a user and other than 0. Further, instead of using the constant metric a0, a variable metric in which the value is variable in accordance with a decoding state and the like.

In this manner, in the second compare unit 16, the path metric PM at the current time obtained by the first compare unit 14 is used as it is for the sampling data inputted so as to obtain the minimum path metric at the next time. In the path memory 18, with the additional selection signal sg2, the decoding is performed with respect to the sampling data not inputted into the branch metric calculator 12.

As described above, in the Viterbi decoder 8, when the branch metric addition is not performed by the add unit 13 by no sampling data input, the second compare unit 16 and the second select unit 17 perform the comparison and the selection, and the additional selection signal sg2 generated thereby is outputted to the path memory 18. Further, when the branch metric addition is performed by the add unit 13, the first select unit 15 and the first compare unit 14 perform the comparison and the selection, and the selection signal sg1 generated thereby is outputted to the path memory 18.

In the path memory 18, by utilizing the selection signal sg1 and additional selection signal sg2, the digital data can be decoded when the sampling data is inputted and also when the sampling data is not inputted.

In the manner as described above, the following operation and effect can be obtained. In the Viterbi decoder 8, it is configured so that the calculation of the branch metric by the branch metric calculator 12, the addition of the branch metric by the add unit 13, the comparison of the path metrics in the respective paths by the first compare unit 14 and the second compare unit 16, the selection of the path metric and the output of the selection signals sg1, sg2 to the path memory 18 by the first select unit 15 and the second select unit 17 are all executable at the one-half operating frequency of that of the channel rate Viterbi decoder. Therefore, the operating frequency in the Viterbi decoder 8 is reduced to a half, allowing the power consumption in the data reproducing apparatus 1 to be reduced.

Meanwhile, for the optical disks: DVD and HV DVD, a channel bit length called a T length and a sampling frequency (hereinafter called the “channel rate frequency”) defining the channel bit length as a Nyquist frequency are defined.

In the case of the DVD, when accessing at a stationary linear single speed, the channel rate frequency is 26.16 MHz. In the case of the HD DVD, it is 64.8 MHz. In general, the processing is performed at these channel frequencies. In the case of the DVD, 3 T is a minimum mark/space length. In the case of the HD DVD and a Blu-ray Disc, 2 T is the minimum mark/space length.

As has been described, based on the sampling theorem, it is considered that no large information miss arises even when the sampling is performed at the one-half frequency of the channel bit rate, so that the sampling can be performed at the half-rate clock by reducing the channel bit rate to the one-half frequency. With this, the number of input data into the Viterbi decoder 8 can be reduced to a half. In addition, the operating frequency of the Viterbi decoder itself can also be reduced to a half.

Note that, in the embodiment above, the case where the Viterbi decoder 8 is applied to the data reproducing apparatus 1 based on the HD DVD is used by way of example, whereas the embodiment is also applicable to the data reproducing apparatus based on the DVD or the Blu-ray Disc.

Further, according to the Viterbi decoder 8 related to the embodiment of the invention, the input data series into the branch metric calculator 12 can be reduced to a half rate of the conventional one.

With this, in the data reproducing apparatus 1, the operating frequencies of the AD converter 5, the adaptive equalizer 7 and the like provided in the stage prior to the Viterbi decoder 8 can be reduced to a half. Accordingly, the power consumption can be reduced as well.

In the conventional arts, a data interpolating device, which convert data into the channel bit rate in the stage prior to the Viterbi decoder while reading out the data from the optical disk at the one-half rate is needed (for example, refer to FIG. 12 and the like in Japanese Patent Application Publication (KOKAI) No. 2002-269925).

However, in the Viterbi decoder 8 according to the embodiment of the invention, even when no data is inputted into the branch metric calculator 12, the comparison and the selection with respect to the path metrics are performed by the second compare unit 16 and the second select unit 17, and thereby the path selection signal is outputted, eliminating the need of the data interpolating device as described above. In the Viterbi decoder 8, the data interpolation by the data interpolating device is not necessary, and therefore the digital data can be decoded at the half-rate clock.

In the Viterbi decoder 8 according to the embodiment of the invention, the provision of a data interpolating circuit is not necessary. Notwithstanding the above, the Viterbi decoder 8 can decode the digital data at the one-half rate, so that the calculation process of the branch metrics in the branch metric calculator 12 can be reduced to a half. With this, the Viterbi decoder 8 can reduce the operating frequency and the power consumption.

### Second Embodiment

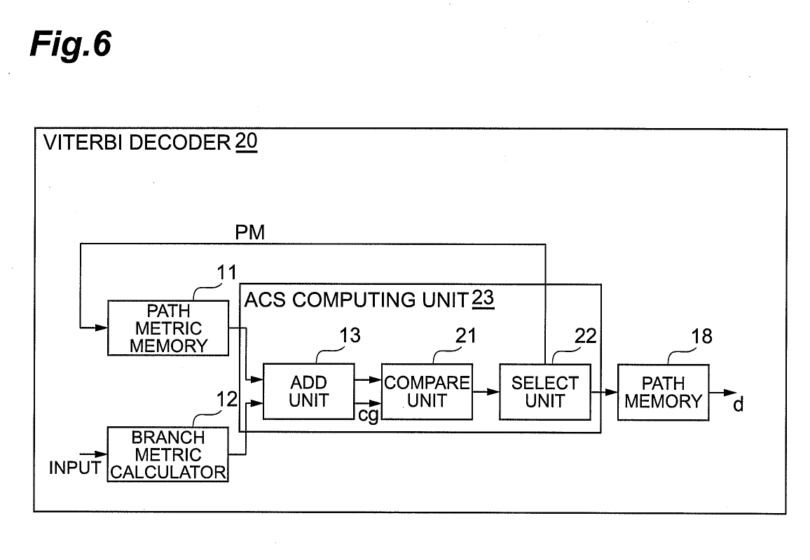

Subsequently, the description will be given of a Viterbi decoder 20 according to a second embodiment with reference to FIG. 6. In comparison with the Viterbi decoder 8, in view of a difference, the Viterbi decoder 20 includes an ACS computing unit 23 in place of the ACS computing unit 19 as shown in FIG. 6, and, in the other respect, the Viterbi decoders 8, 20 are the same.

The ACS computing unit 23 includes the add unit 13 as in the ACS computing unit 19. However, the ACS computing unit 23 does not include the first compare unit 14, the first select unit 15, the second compare unit 16 and the second select unit 17, but includes a compare unit 21 and a select unit 22. The compare unit 21 is that combining the first compare unit 14 and the second compare unit 16 into a single unit, carrying both the functions together. Further, the select unit 22 is that combining the first select unit 15 and the second select unit 17 into a single unit, carrying both the functions together.

As shown in FIG. 6, a control signal cg is inputted into the compare unit 21. The control signal cg indicates whether the branch metric addition by the add unit 13 is performed or not. For instance, the control signal cg can be generated by the add unit 13 (in that case, the add unit 13 carries a function as a control signal generator).

When the control signal cg indicates that the branch metric addition is performed by the add unit 13, the compare unit 21 performs the operation as the first compare unit 14 and when not, the compare unit 21 performs the operation as the second compare unit 16. With the compare unit 21 performing the operation as described above, the path metric when the sampling data is inputted and the path metric when the sampling data is not inputted are outputted alternately. Based on this, the Viterbi decoder 20 can decode the digital data in the same manner as in the Viterbi decoder 8.

### Third Embodiment

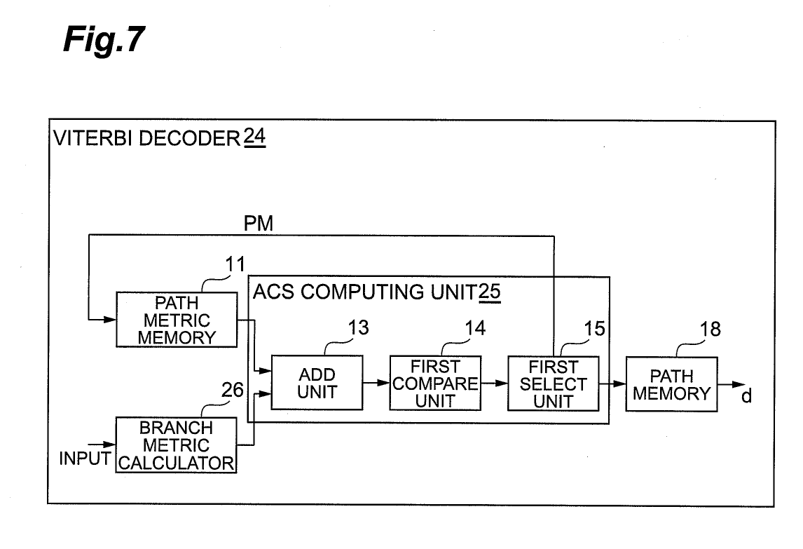

Subsequently, the description will be given of a Viterbi decoder 24 according to a third embodiment with reference to FIG. 7. In comparison with the Viterbi decoder 8, in view of a difference, the Viterbi decoder 24 includes an ACS computing unit 25 and a branch metric calculator 26 in place of the ACS computing unit 19 and the branch metric calculator 12, respectively, as shown in FIG. 7, and, in the other respect, the Viterbi decoders 8, 24 are the same.

The ACS computing unit 25 includes the add unit 13, the first compare unit 14 and the first select unit 15, but does not include the second compare unit 16 and the second select unit 17. The ACS computing unit 25 is in common with the ACS computing unit of the channel rate Viterbi decoder.

When the data is inputted, the branch metric calculator 26 calculates and outputs the branch metrics of all the paths from that at the current state to that at the state of the next time, and when no data is inputted, the constant metric a0 is outputted as a branch metric. By doing in this manner, even the time at which no sampling data is inputted, the path metric can be obtained by the equation 5 and the equation 6. Hence, the Viterbi decoder 24 can decode the digital data in the same manner as in the Viterbi decoder 8.

Note that, in the above embodiments, the data reproducing apparatus 1 using the optical disk as a recording medium is described as an example, however, the invention is not limited to the apparatus using the optical disk as a recording medium, and the invention is also applicable to the hard disk drive using the MR head.

Further, in the above-described respective embodiments, the most probable path is selected by selecting the path metric having the smaller value, whereas the most probable path may be selected by selecting the path metric having the larger value.

In the above embodiments, the Viterbi decoders 8, 20, 24 are described as examples, however, the Viterbi decoder of a different configuration is also acceptable. Specifically, any Viterbi decoder is acceptable as long as the Viterbi decoder includes the path computing device configured to select the maximum-likelihood path by utilizing the path metric of the selected maximum-likelihood path as it is.

The above-described description is to describe the embodiments of the invention and is not intended to limit the device and the method of the invention, allowing various modification examples to be embodied with ease. Further, the device and the method composed by appropriately combining the components, the functions, the characteristics and the steps of method of the respective embodiments are also within the scope of the invention.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A digital data decoding apparatus comprising:
a branch metric calculating device configured to calculate branch metrics of all paths in an input data series from the path at a state of a current time to the path at a state of a next time; and
a path computing device configured to add a branch metric calculated by said branch metric calculating device to a path metric of the path corresponding to the branch metric to obtain the path metrics of all the paths up to the path at the state of the next time, and to select a maximum-likelihood path from among the paths based on the obtained path metrics,
wherein the path computing device is configured to select the maximum-likelihood path by utilizing the path metrics of the selected maximum-likelihood path without adding the branch metric thereto.

2. A digital data decoding apparatus comprising:
a branch metric calculating device configured to calculate branch metrics of all paths in an input data series from the path at a state of a current time to the path at a state of a next time;
an add device configured to obtain path metrics of all the paths up to the path at the state of the next time by adding a branch metric calculated by said branch metric calculating device to the path metric of the path corresponding to the branch metric;
a compare device configured to compare the path metrics of the all the paths obtained by said add device to obtain a smallest or largest path metric; and
a path select device configured to select the path corresponding to the smallest or largest path metric obtained by said compare device, as a maximum-likelihood path among the paths,
wherein the compare device is configured to use the smallest or largest path metric without adding a branch metric thereto to obtain a path metric for addition when the branch metric is not added by said add device, and
wherein the path select device is configured to select the path corresponding to the path metric for addition as the maximum-likelihood path when a branch metric is not added by said add device.

3. A digital data decoding apparatus according to claim 2, further comprising:
a second compare device configured to obtain a path metric for addition by utilizing the smallest or largest path metric without adding the branch metric thereto when a branch metric is not added by said add device; and
a second path select device configured to select the path corresponding to the path metric for addition as the maximum-likelihood path when a branch metric is not added by said add device.

4. A digital data decoding apparatus according to claim 1, wherein said branch metric calculating device is configured to output a constant metric set to a determined value as the branch metric when data composing the input data series is not inputted.

5. The digital data decoding apparatus according to claim 1, further comprising a path metric memory device configured to store the path metric of the maximum likelihood path selected by said path computing device.

6. The digital data decoding apparatus according to claim 2, further comprising a path metric memory device configured to store the path metric of the maximum likelihood path selected by said path select device.

7. The digital data decoding apparatus according to claim 1, further comprising a control signal generating device configured to generate a control signal indicating whether the branch metric is added or not.

8. The digital data decoding apparatus according to claim 2, further comprising a control signal generating device configured to generate a control signal indicating whether the branch metric is added or not.

9. The digital data decoding apparatus according to claim 3, further comprising a control signal generating device configured to generate a control signal indicating whether the branch metric is added or not.

10. The digital data decoding apparatus according to claim 4, further comprising a control signal generating device configured to generate a control signal indicating whether the branch metric is added or not.

11. The digital data decoding apparatus according to claim 1, wherein said path computing device is configured to perform a path metric computation by utilizing a constant metric when data composing the input data series is not inputted into said branch metric calculating device.

12. A digital data decoding method, comprising:
calculating branch metrics of all paths in an input data series from the path at a state of a current time to the path at a state of a next time,
adding the calculated branch metric to a path metric of the path corresponding to the branch metric to obtain the path metrics of all the paths up to the path at the state of the next time, and selecting a maximum-likelihood path from among the obtained paths based on the obtained path metrics, and
selecting the maximum-likelihood path by utilizing the path metric of the selected maximum-likelihood path without adding a branch metric thereto when an input is not performed.
